(19) United States
(12) Patent Application Publication
(10) Pub. No.: US 2004/0121265 A1
(43) Pub. Date: Jun. 24, 2004

(54) Technique for reducing resist poisoning in forming a metallization layer including a low-k dielectric

(76) Inventors: Thomas Werner, Dresden (DE); Hartmut Ruelke, Dresden (DE); Christof Streck, Coswig (DE)

Correspondence Address: Mike Amerson, Williams, Morgan & Amerson, P.C., Suite 1100, 10333 Richmond, Houston, TX, 77042, US

(21) Appl. No.: 10/691,274

(22) Filed: Oct. 22, 2003

(30) Foreign Application Priority Data
Dec. 23, 2002 (DE) 102 60 615.3

(51) Int. Cl. G03F 7/00

(52) U.S. Cl. 430/311

(57) ABSTRACT

During the formation of a metallization layer according to the “via first, trench last” sequence with a low-k dielectric layer, resist poisoning is significantly reduced in that a low-density oxide layer is formed on the low-k dielectric layer, for example by converting an upper portion thereof into an oxide so that prior to and during the formation of the cap layer, out-gassing of volatile materials is enhanced. Since the density of the cap layer is reduced compared to cap layers formed by conventional deposition techniques, out-gassing may still be maintained across the entire substrate surface during the via and trench formation so that a critical level of resist contamination may reliably be avoided.

### BACKGROUND OF THE INVENTION

1. Field of the Invention

Generally, the present invention relates to the formation of integrated circuits, and, more particularly, to the formation of metallization layers including metals, such as copper, embedded into a dielectric material having low permittivity to enhance device performance.

2. Description of the Related Art

In modern integrated circuits, minimum feature sizes, such as the channel length of field effect transistors, have reached the deep sub-micron range, thereby steadily increasing performance of these circuits in terms of speed and power consumption. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines have to be reduced to compensate for a reduced amount of available floor space and for an increased number of circuit elements provided per chip. In integrated circuits having minimum dimensions of approximately 0.35 μm and less, a limiting factor of device performance is the signal propagation delay caused by the switching speed of the transistor elements. As the channel length of these transistor elements has now reached 0.18 μm and less, it turns out, however, that the signal propagation delay is no longer limited by the field effect transistors but is limited, owing to the increased circuit density, by the close proximity of the interconnect lines, since the line-to-line capacitance is increased in combination with a reduced conductivity of the lines due to their reduced cross-sectional area. The parasitic RC time constants therefore require the introduction of a new type of material for forming the metallization layer.

Traditionally, metallization layers are formed by a dielectric layer stack including, for example, silicon dioxide and/or silicon nitride with aluminum as the typical metal. Since aluminum exhibits significant electromigration at higher current densities that may be necessary in integrated circuits having extremely scaled feature sizes, aluminum is being replaced by copper, which has a significantly lower electrical resistance and a higher resistivity against electromigration. For devices having feature sizes of 0.13 μm and less, it turns out that simply replacing aluminum with copper does not provide the required decrease of the parasitic RC time constants, and, therefore, the well-established and well-known dielectric materials silicon dioxide (k approximately 4.2) and silicon nitride (k>5) are increasingly replaced by so-called low-k dielectric materials. However, the transition from the well-known and well-established aluminum/silicon dioxide metallization layer to a low-k dielectric/copper metallization layer is associated with a plurality of issues to be dealt with.

For example, copper may not be deposited in higher amounts in an efficient manner by well-established deposition methods, such as chemical and physical vapor deposition. Moreover, copper may not efficiently be patterned by well-established anisotropic etch processes and therefore the so-called damascene technique is employed in forming metallization layers including copper lines. Typically, in the damascene technique, the dielectric layer is deposited and then patterned with trenches and vias that are subsequently filled with copper by plating methods, such as electroplating or electroless plating. Although the damascene technique is presently a well-established technique for forming copper metallization layers in standard dielectric materials, such as silicon dioxide, the employment of low-k dielectrics requires the development of new dielectric diffusion barrier layers so as to avoid copper contamination of adjacent material layers, as copper readily diffuses in a plurality of dielectrics. Although silicon nitride is known as an effective copper diffusion barrier, silicon nitride is not an option in low-k dielectric layer stacks owing to its high permittivity. Therefore, presently, silicon carbide is considered as a viable candidate for a copper diffusion barrier. It turns out, however, that copper's resistance against electromigration strongly depends on the interface between the copper and the adjacent diffusion barrier layer, and, therefore, in sophisticated integrated circuits featuring high current densities, it is generally preferable to use up to 20% nitrogen in the silicon carbide layer, thereby remarkably improving the electromigration behavior of copper compared to pure silicon carbide.

A further problem in forming low-k copper metallization layers has been underestimated in the past and is now considered a major challenge in the integration of low-k dielectrics. During the patterning of the low-k dielectric material, standard photolithography is used to image the required structure into the deep UV photoresist. In developing the photoresist, certain portions of the resist, which have been exposed, may not be completely removed as required and thus the structure may not be correctly transferred into the underlying low-k dielectric material. The effect of insufficiently developing the photoresist is also referred to as resist poisoning. With reference to FIGS. 1a-1e, a typical conventional process flow will now be described to explain the problems involved in forming a metallization layer including copper and a low-k dielectric in more detail.

FIG. 1a schematically shows a cross-sectional view of a semiconductor structure 100, in which a low-k dielectric material is to be patterned in accordance with a so-called via first/trench last process sequence, which is presently considered as the most promising process scheme in patterning low-k dielectrics. The semiconductor structure 100 comprises a substrate 101 that may include circuit elements, such as transistors, resistors, capacitors and the like, and which may include a lower metallization layer 102 including a metal region 103 embedded in a dielectric material 104. Depending on the level of the lower metallization layer 102, the metal region 103 may comprise copper and the dielectric 104 may be a low-k dielectric, such as hydrogen-containing silicon oxycarbide (SiCOH). A barrier layer 105 formed of nitrogen-containing silicon carbide (SiCN), which also serves as an etch stop layer in the following etch procedure for patterning an overlying low-k dielectric layer 106, is formed above the layer 104. The low-k dielectric layer 106 may comprise, depending on the process sequence used, an intermediate silicon carbide etch stop layer 107, which in many applications may, however, be omitted for the benefit of a reduced total permittivity. The low-k dielectric material in the layer 106 may comprise SiCOH. A cap layer 108, for example comprised of oxide, is located over the low-k dielectric layer 106 and may also serve as a stop layer in removing excess copper in a subsequent chemical mechanical polishing (CMP) processes. A resist mask 109 including an opening 110 is formed above the cap layer 108.

A typical process flow for forming the semiconductor structure 100 as shown in FIG. 1a may comprise the following steps. After planarizing the lower metallization layer 102, the barrier/etch stop layer 105 is deposited, for example by plasma enhanced chemical vapor deposition (PECVD) from trimethyl silane (3MS) and ammonia (NH₃) as precursor gases. Then, the hydrogen-containing silicon oxycarbide is deposited, wherein, if required, the silicon carbide layer 107 is formed when a first required thickness of the dielectric layer 106 is obtained. Thereafter, the residual layer 106 is deposited to achieve the required overall thickness of the layer 106. It should be noted that, owing to the low density of the low-k material of the layer 106, volatile materials, such as nitrogen and nitrogen compounds, may readily diffuse in the dielectric layer 106. The nitrogen and nitrogen compounds may originate from the etch stop layer 105 and/or from precursor gases used during the processing of the semiconductor structure 100.

Next, the cap layer 108 is deposited with a required thickness. The cap layer 108 substantially avoids any interaction of the low-k dielectric of the layer 106 with the overlying resist mask 109. Then, the resist mask 109 is patterned in accordance with well-established deep UV lithography techniques to form the opening 110 determining the dimensions of the vias to be formed within the dielectric layer 106.

FIG. 1b schematically shows the semiconductor structure 100 after an anisotropic etch process for forming a via 111 in the cap layer 108 and the dielectric layer 106. During the anisotropic etch procedure, the barrier/etch stop layer 105 exhibits a significantly lower etch rate than the surrounding dielectric layer 106, so that the etch process may be stopped in or on the layer 105. Thereafter, the remaining photoresist not consumed during the anisotropic etch process is removed by an etch step in an oxygen-containing plasma ambient. Since the cap layer 108 substantially prevents any diffusion from nitrogen or nitrogen-containing compounds into the overlying resist mask 109, the patterning of the opening 110 and the subsequent patterning of the via 111 is substantially not affected by any resist poisoning effects.

FIG. 1c schematically shows the semiconductor structure 100 in an advanced manufacturing stage. The via 111 is filled with an organic anti-reflective coating material so as to include a via plug 114, whereas the organic material is provided at the remaining surface of the structure 100 so as to form an anti-reflective coating layer 112 for the subsequent photolithography. Thus, the plug 114 and the anti-reflective coating 112 serve to planarize the topography of the semiconductor structure 100 prior to the formation of a further photoresist mask 113. As shown, the photoresist mask 113 includes a trench opening 115 at the bottom of which resist residuals 116 remain.

The via plug 114, formed of the anti-reflective coating material and acting to planarize the surface topography, and the anti-reflective coating 112 may be formed by spin-on techniques and the like, and the photoresist mask 113 may be formed by sophisticated lithography methods, as are well known in the art. Contrary to the formation of the resist mask 109, nitrogen or nitrogen compounds may readily diffuse through the organic anti-reflective coating material and may now come into contact with the overlying photoresist 113, since the protecting cap layer 108 is open at the via 111. The interaction of nitrogen and compounds thereof with the photoresist may deteriorate the light sensitivity of the resist. Consequently, upon exposure and development of the photoresist 113 in forming the trench opening 115, the resist residuals 116 remain and significantly affect the following anisotropic etch step for forming a trench in the upper portion of the dielectric layer 106.

FIG. 1d schematically shows the semiconductor structure 100 after completion of the trench forming step. As is evident from FIG. 1d, the trench 117 that should have been formed in the dielectric layer 106 does not substantially represent the dimensions of the overlying photoresist mask 113 used to etch the pattern of the photoresist mask 113 into the underlying cap layer 108 and the upper portion of the dielectric layer 106. Thus, after removing the remaining photoresist mask 113, the cap layer 108 and the dielectric layer 106 comprise substantially the via 111 without any trench in the upper portion of the layer 106. It should be noted that even a significant increase of the thickness of the anti-reflective coating 112 may not efficiently prevent the overlying photoresist layer 113 from interacting with up-diffusing nitrogen-containing compounds.

FIG. 1e schematically shows the semiconductor structure 100 after completion of the metallization layer 130 including a barrier metal layer 118 on inner sidewalls and the bottom of the via 111, which is filled with copper 119. Moreover, a surface 120 of the metallization layer 130 is planarized to allow the formation of a further metallization layer.

Typically, the barrier metal layer 118 may be deposited by physical vapor deposition, such as sputter deposition, with a thickness that insures sufficient protection against copper out-diffusion and, at the same time, provides the required adhesion to the surrounding low-k dielectric material. Typically, tantalum or tantalum nitride may be used as material for the barrier metal layer 118. Subsequently, a copper seed layer is deposited to promote the subsequent deposition of the bulk copper by electroplating. Then, the excess copper is removed by chemical mechanical polishing, wherein the cap layer 108 is also removed and acts as a stop layer to reliably control the CMP process. However, since the trenches 117 required for the electrical connection are missing, as shown in FIGS. 1d and 1e, or are at least substantially reduced in size, device failures consequently occur or at least a significantly reduced device reliability is obtained.

In view of the above problems, it is thus highly desirable to provide a technique that reduces resist poisoning in the formation of low-k metallization layers.

### SUMMARY OF THE INVENTION

In general, the present invention is based on the finding that a critical level of out-diffusing species from via holes that cause an intolerable degree of resist poisoning when patterning trenches may effectively be avoided in that these species are allowed to out-gas prior to and throughout the formation of a cap layer of reduced density. Moreover, the reduced density of the cap layer also allows a certain degree of diffusion of resist poisoning species during the formation of a resist mask so that the out-diffusion of the species is no longer restricted to the region within the via hole, thereby efficiently reducing the degree of resist contamination to an uncritical level.

According to one illustrative embodiment of the present invention, a method of forming a low-k metallization layer comprises the formation of a low-k dielectric layer over a substrate and converting an upper portion of the low-k dielectric layer into a protective dielectric so as to provide a sacrificial cap layer. The sacrificial cap layer and the low-k dielectric layer are then patterned with a resist mask formed over the sacrificial cap layer.

According to still another embodiment of the present invention, a method comprises forming a silicon-based low-k dielectric layer over a substrate and forming a sacrificial silicon dioxide layer on the low-k dielectric layer. Then, the sacrificial silicon dioxide layer and the low-k dielectric layer are patterned with a resist mask, wherein volatile materials are allowed to out-diffuse from the low-k layer prior to, during and after the formation of the low-density sacrificial silicon dioxide layer.

### BRIEF DESCRIPTION OF THE DRAWINGS

The invention may be understood by reference to the following description taken in conjunction with the accompanying drawings, in which like reference numerals identify like elements, and in which:

FIGS. 1a-1e schematically show a conventional semiconductor structure during various manufacturing stages in forming a low-k dielectric metallization layer in a so-called “via first, trench last” damascene sequence; and

FIGS. 2a-2h schematically show cross-sectional views of a semiconductor structure including a low-k metallization layer during various manufacturing stages in accordance with one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

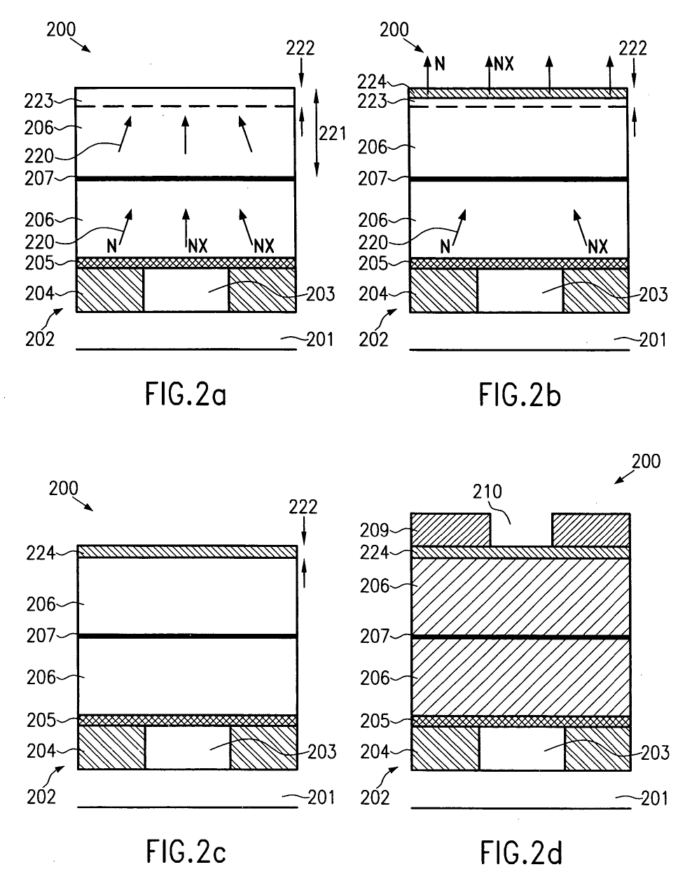

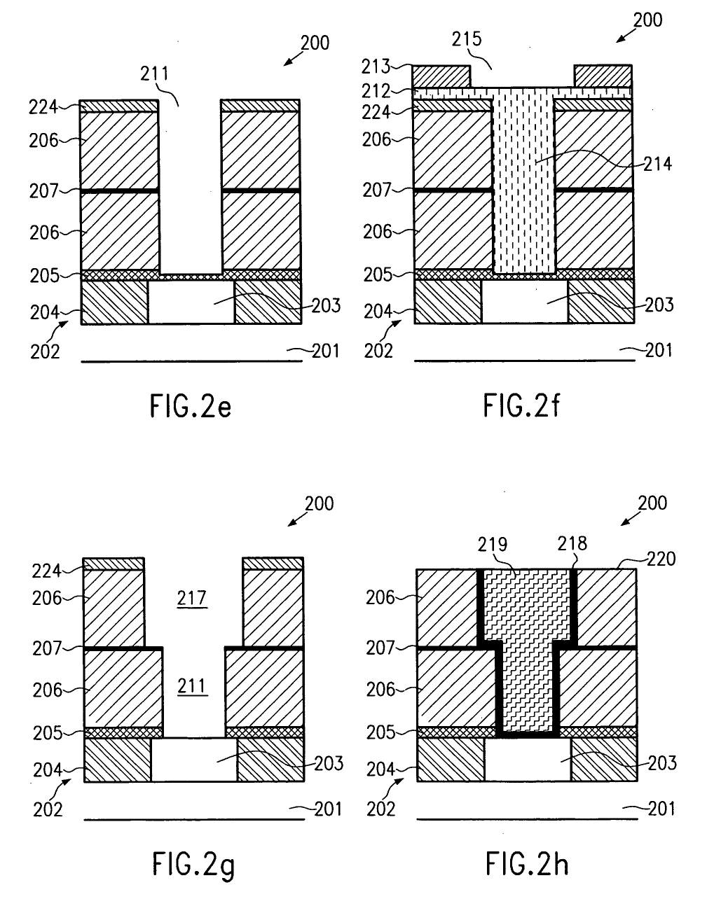

With reference to FIGS. 2a-2d, further illustrative embodiments of the present invention will now be described. FIG. 2a schematically shows a semiconductor structure 200 including a substrate 201, which may have formed thereon a metallization layer 202, for example including a metal region 203 embedded into an insulating material 204. It should, however, be appreciated that the metallization layer 202 may represent any portion of an integrated circuit, and therefore the metallization layer 202 may also represent metal contacts immediately connected to circuit elements such as transistors, capacitors, resistors and the like. An etch stop/barrier layer 205 is formed over the layer 202, wherein the etch stop layer 205 may be formed of a low-k material, such as silicon carbide, that may contain a certain amount of nitrogen to provide the required barrier characteristics when the underlying metal region 203 comprises copper. A low-k dielectric layer 206 is formed over the etch stop layer 205, wherein an intermediate etch stop layer 207, for example comprised of silicon carbide, may optionally be provided. In one particular embodiment, the low-k dielectric layer is substantially comprised of a silicon-containing low-k material, such as hydrogen-containing silicon oxide carbide (SiCOH) or SiLK. A thickness of the dielectric layer 206 or at least of an upper portion, indicated by 221, is selected when the intermediate etch stop layer 207 is provided so as to exceed a desired design thickness by a specified amount as indicated by reference number 222. Providing the excess thickness 222 enables the conversion of a surface portion 223 into a low-density cap layer, as will be described in more detail with reference to FIG. 2b.

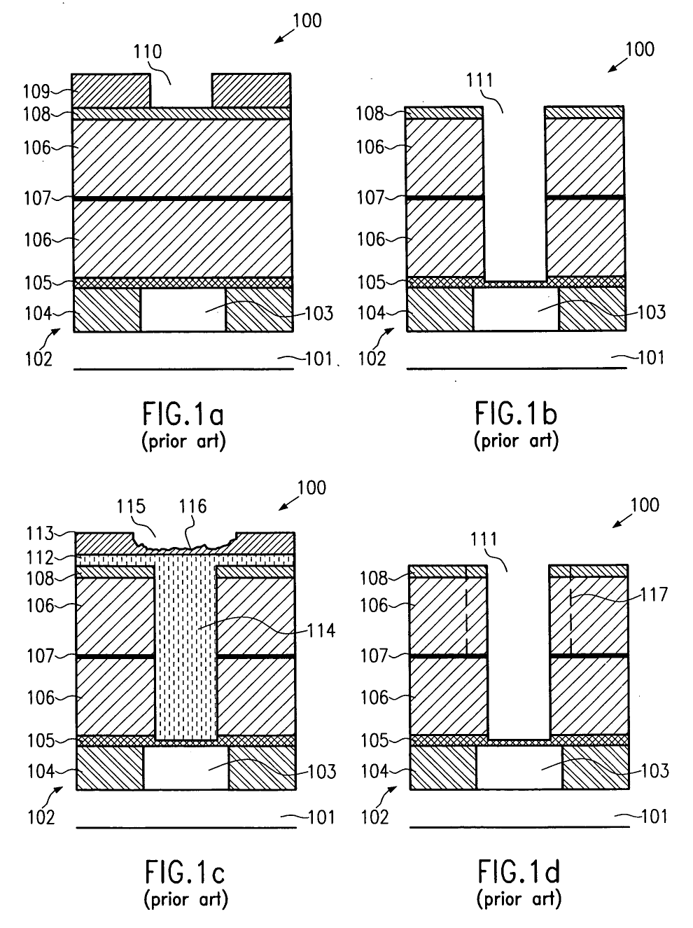

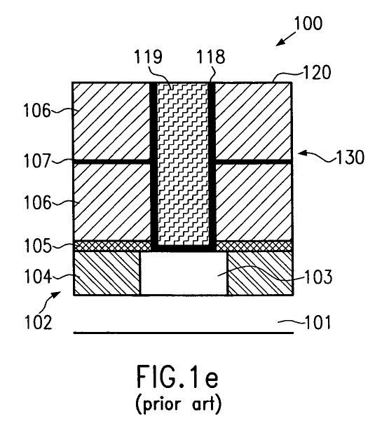

A typical process flow for forming the semiconductor structure 200 as shown in FIG. 2a may substantially include the same process steps as already described with reference to FIG. 1a, except for the omission of depositing a cap layer on top of the low-k dielectric layer 206. Moreover, the deposition process for forming the low-k dielectric layer 206 is controlled in such a way that the surface portion 223 with the required thickness 222 is obtained. As previously explained, volatile materials 220, and especially nitrogen and nitrogen compounds, may diffuse into and within the low-k dielectric layer 206. Especially when the etch stop layer 205 comprises a relatively high amount of nitrogen, for example, for improving the barrier and electromigration properties with respect to the underlying metal region 203, nitrogen and nitrogen compounds may readily diffuse into the layer 206. Furthermore, the employment of nitrogen-containing precursor gases in any process steps for forming the etch stop layer 205 and/or the low-k dielectric layer 206 may lead to minute amounts of nitrogen or nitrogen compounds trapped in these layers, which then readily diffuse within the low-k dielectric layer 206. In one embodiment, after completion of the deposition of the low-k dielectric layer 206, the semiconductor structure 200 may be subjected to a heat treatment in a substantially nitrogen-free atmosphere to thereby promote the out-gassing of the volatile materials 220 and especially of nitrogen and nitrogen compounds. To this end, the semiconductor structure 200 may be inserted into a different process chamber or may be maintained within the deposition chamber, wherein supply of the precursor gases, such as 3MS and other reactive gases, is discontinued and a pump step is initiated to decrease the pressure within the process chamber to a range of approximately some millitorrs, wherein simultaneously the temperature of the semiconductor substrate 201 is maintained to a range of approximately 300-500° C. Due to the low ambient pressure and the elevated temperature, diffusion and thus out-gassing of the volatile materials 220 is promoted. The heat treatment at an elevated temperature and reduced ambient pressure may be carried out for approximately 10-30 seconds.

In other embodiments, the heat treatment as described above may be omitted and a reactive plasma ambient may be established in the same process chamber as used for the deposition of the low-k dielectric layer 206, or, in other embodiments, a different process chamber may be used, wherein the plasma ambient contains oxygen. For example, oxygen may be introduced with a flow rate in the range of approximately 300-800 sccm and a pressure of the plasma ambient of approximately 3-5 Torr, wherein the high frequency power for establishing the plasma ambient is in the range of approximately 200-700 Watts. Additionally, a bias power of 10-100 Watts may be applied to enhance the directionality of the oxygen ions with respect to the substrate 201. The additional oxygen arriving at the surface portion 223 of the low-k dielectric layer 206 leads to an oxidation process, wherein low-k material is consumed to generate a dielectric material having a higher k value than the initially deposited low-k material 206. In the particular embodiment in which the low-k layer 206 comprises a silicon-containing material such as SiCOH or SiLK, a surface layer is created comprising a high degree of silicon dioxide. The ratio of silicon dioxide to low-k material may depend on the plasma conditions, wherein, for example, the pressure and/or the oxygen flow rate of the plasma ambient may be controlled to vary the ratio. By varying this ratio, the degree of density or porosity of the silicon dioxide in the surface portion 223 may be controlled.

FIG. 2b schematically shows the semiconductor structure 200 during the plasma treatment as described above. In the surface portion 223, a silicon dioxide comprising layer 224 is formed, whereby the density thereof is, however, significantly lower than the density of a deposited silicon dioxide layer, as described, for example, with reference to FIG. 1a in the conventional process flow. Furthermore, due to the amount of silicon dioxide in the layer 224, the permittivity thereof is increased compared to the portion 223. Since the layer 224 will serve as a sacrificial cap layer for the further processing of the semiconductor structure 200, no device degradation is related with converting an upper portion of the low-k dielectric layer 206 to a high-k dielectric. During the ongoing conversion of low-k material into oxide, thereby continuously consuming the surface portion 223, the volatile materials 220 may out-gas through the entire surface of the layer 224 due to the reduced density thereof.

FIG. 2c schematically shows the semiconductor structure 200 after completion of the above-described plasma treatment wherein the sacrificial cap layer substantially exhibits the thickness 222. In typical examples, the thickness 222 may be in the range of approximately 30-100 nm, which may be obtained for the above-specified process parameters within a time interval of approximately 10-20 seconds. It should be noted that even with the full thickness 222, the sacrificial cap layer 224 allows the out-gassing of the volatile materials 220 since the reduced density compared to a conventionally deposited cap layer, such as the cap layer 105 shown in FIG. 1a, provides a certain porosity.

FIG. 2d schematically shows the semiconductor structure 200 with a resist mask 209 including an opening 210 formed on the sacrificial cap layer 224. Although a certain degree of out-gassing may still occur during the formation of the resist mask 209, the level of resist contamination within the mask 209 may be below critical level due to the previously enhanced diffusion and out-gassing rate for the volatile material 220. Thus, the opening 210 may be formed in accordance with design requirements as substantially no resist residuals are produced. In some embodiments, prior to the formation of the resist mask 209, a sacrificial resist layer may be formed on the sacrificial cap layer 224 and a test photolithography process, i.e., an exposure and development process, may be carried out so as to monitor the presently prevailing out-gassing rate and thus the amount of resist residuals that has to be expected in forming the resist mask 209. If the created residuals exceed a certain specified threshold, a further heat treatment may be carried out to further promote the out-gassing of the volatile material 220.

FIG. 2e schematically shows the semiconductor structure 200 having formed in the dielectric layer 206 and the sacrificial layer 224 a via 211 in conformity with the opening 210. The process flow for forming the via 211 may include substantially the same process steps as already described with reference to FIG. 1b.

In FIG. 2f, the semiconductor structure 200 is shown with an anti-reflective material provided in the form of a layer 212 and a via plug 214, and with a resist mask 213 formed on the anti-reflective layer 212. The resist mask 213 includes a trench opening 215 having dimensions as specified by design requirements. Contrary to the conventional process flow as described in FIG. 1c, the sacrificial cap layer 224 allows out-gassing of volatile materials during the entire process sequence, so that during formation of the resist mask 209 and especially during formation of the resist mask 213, the level of resist contamination may reliably be maintained below a specified threshold. Thus, out-gassing of the volatile materials 220 is no longer restricted to the regions surrounding the via 211, but takes place substantially all over the entire surface of the sacrificial cap layer 224. Thus, resist residuals may sufficiently be avoided or may at least be maintained at a level that does not unduly compromise the resist development to define the trench opening 215.

FIG. 2g schematically shows the semiconductor structure 200 with the via 211 formed in the lower portion of the low-k dielectric layer 206 and the etch stop layer 205 and with a trench 217 formed in the upper portion of the low-k dielectric layer 206 and the sacrificial cap layer 224. Due to the reduced resist contamination of the resist mask 213, the dimensions of the trench 217 substantially correspond to those of the trench opening 215.

FIG. 2h schematically shows the semiconductor structure 200 after completion of final process steps, as are already described with reference to FIG. 1e. The semiconductor structure 200 comprises a copper trench and a copper via, both indicated by 219, providing electrical contact to the underlying metal region 213. A conductive barrier layer 218 may be provided on inner surfaces of the trench 217 and the via 211. The sacrificial cap layer 224 is removed so as to provide a substantially planar surface 230 required for the further processing of the semiconductor structure 200.

Hence, the present invention allows one to reliably obtain the metal trenches 219 in the upper portion of the low-k dielectric layer 206 in that the diffusion and the out-gassing of volatile material in this layer is significantly enhanced prior to formation of a respective resist mask. Therefore, resist contamination may be maintained well below a critical resist poisoning level.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a low-k dielectric layer over a substrate;
converting an upper portion of said low-k dielectric layer into a protective dielectric to form a sacrificial cap layer; and
patterning said sacrificial cap layer and said low-k dielectric layer.

2. The method of claim 1, wherein converting an upper portion of said low-k dielectric layer includes exposing said substrate to an oxidizing plasma ambient.

3. The method of claim 2, wherein said low-k dielectric layer comprises a silicon-based dielectric material.

4. The method of claim 1, wherein said low-k dielectric layer is formed with a thickness that exceeds a desired final design thickness of said low-k dielectric layer.

5. The method of claim 4, wherein converting said upper portion is continued until the thickness of said low-k dielectric layer substantially corresponds to said design thickness.

6. The method of claim 1, further comprising heat treating said substrate prior to converting said upper portion of said low-k dielectric layer to promote out-gassing of volatile materials.

7. The method of claim 1, further comprising forming a first resist mask over said sacrificial cap layer and etching a via opening through said sacrificial cap layer and said low-k dielectric layer, wherein resist contamination of said first resist mask is maintained below a specified level.

8. The method of claim 7, further comprising forming a second resist mask over said sacrificial cap layer and patterning an upper portion of said low-k dielectric layer to form a trench over said via opening, the trench having a greater lateral dimension than said via opening.

9. The method of claim 7, further comprising determining a contamination level of photoresist prior to forming said first resist mask.

10. The method of claim 9, further comprising heat treating said substrate to further out-gas said volatile material through said sacrificial cap layer when said determined contamination level exceeds a predefined level.

11. A method, comprising:
forming a silicon-based low-k dielectric layer over a substrate; and
forming a silicon dioxide layer as a sacrificial cap layer on said low-k dielectric layer, wherein volatile materials out-gas from said low-k dielectric layer prior to and during the formation of said silicon dioxide layer.

12. The method of claim 11, wherein forming said silicon dioxide layer includes converting an upper portion of said low-k dielectric layer into low-density silicon dioxide.

13. The method of claim 12, wherein said upper portion is converted into silicon dioxide by exposing said substrate to an oxidizing plasma ambient.

14. The method of claim 11, wherein said low-k dielectric layer is formed with a thickness that exceeds a desired final design thickness of said low-k dielectric layer.

15. The method of claims 2 and 4, wherein converting said upper portion is continued until the thickness of said low-k dielectric layer substantially corresponds to said design thickness.

16. The method of claim 11, further comprising heat treating said substrate prior to forming said silicon dioxide layer to promote out-gassing of said volatile materials.

17. The method of claim 11, further comprising forming a first resist mask over said sacrificial cap layer and etching an opening through said sacrificial cap layer and said low-k dielectric layer, wherein resist contamination of said resist mask is maintained below a specified level.

18. The method of claim 17, further comprising forming a second resist mask over said sacrificial cap layer and patterning an upper portion of said low-k dielectric layer to form a trench over said via opening, said trench having a greater lateral dimension than said via opening.

19. The method of claim 17, further comprising determining a contamination level of photoresist prior to forming said first resist mask.

20. The method of claim 19, further comprising heat treating said substrate to further out-gas said volatile material through said sacrificial cap layer when said determined contamination level exceeds a predefined level.
